(19) United States
(12) Patent Application Publication
(10) Pub. No.: US 2010/0147362 A1
(43) Pub. Date: Jun. 17, 2010

(54) MULTI-FUNCTION FRAME AND INTEGRATED MOUNTING SYSTEM FOR PHOTOVOLTAIC POWER GENERATING LAMINATES

(75) Inventors: Zachary Adam King, Townsend, MA (US); Miles Clayton Russell, Lincoln, MA (US); Ruel Davenport Little, Concord, MA (US)

Correspondence Address: Mark J Pandiscio;PANDISCIO & PANDISCIO, 470 TOTTEN POND ROAD, WALTHAM, MA, 02451-1914, US

(73) Assignee: GREENREY, INC., Westford, MA (US)

(21) Appl. No.: 12/450,001

(22) PCT Filed: Feb. 8, 2008
(86) PCT No.: PCT/US2008/001678

§ 371 Date: Feb. 22, 2010

Related U.S. Application Data
(60) Provisional application No. 60/905,398, filed on Mar. 7, 2007.

(51) Int. Cl. H01L 31/048

(52) U.S. Cl. 136/251

(57) ABSTRACT

PV modules are provided that have a frame construction which permits the photovoltaic power-generating cells, DC/AC power conversion means, electrical wiring and other installation aspects to be merged into the module. The modules also are provided with means for coupling them to mounting stands whereby they can be mounted to a roof and also the frame construction is adapted to facilitate mechanically securing adjacent modules to one another.

### FIELD OF INVENTION

This invention relates generally to the manufacture and installation of photovoltaic power generating systems and in particular to a novel approach for using the frames of photovoltaic modules as a significant foundation for integrating those modules into a mounted photovoltaic power generating system. The invention also relates to AC photovoltaic modules and systems.

### BACKGROUND OF INVENTION

The current state of the art of constructing and mounting photovoltaic (PV) modules, and also the integration of an array of such modules into an AC power generating system is evidenced by the disclosures of U.S. Pat. Nos. 5,460,660, issued Oct. 24, 1995 to S. P. Albright et al.; 6,750,391, issued Jun. 15, 2004 to W. I. Bower et al.; 6,959,517, issued Nov. 1, 2005 to J. J. Poddany et al.; 6,465,724, issued Oct. 15, 2002 to P. Garvison et al.; 6,046,399, issued Apr. 4, 2000 to M. Kapner; and 6,593,521, issued Jul. 15, 2003 to T. Kobayashi. The current state of the art is also evidenced by the U.S. Patent Application Publications: U.S. 2006/0219291 of M. Hikosaka et al. published Oct. 5, 2006 and US 2006/0053706 of M. C. Russell published Mar. 15, 2006.

Current photovoltaic power generating building-mounted systems have a variety of limitations. For one thing the typical residential photovoltaic power generating system consists of two or more PV modules bussed together and connected to a single inverter for converting the DC power output of the modules to AC power. Despite the inverter's ability to track the optimal conversion voltage for the system, the system suffers inefficiencies such as module-to-module mismatch, power loss due to varying module orientation and significant shading losses. The single inverter only has the ability to optimize the DC to AC conversion efficiency for the array of modules; it cannot optimize conversion from a single module.

Since the single inverter handles the DC power output of all the modules in an array, it is essential that the single inverter be mounted so that it will be exposed to adequate cooling airflow or be in a conditioned environment in order to operate properly and avoid breakdown due to overheating. As a result the single inverter is usually located near the utility service entrance for the building on which the PV system is mounted, usually on a basement wall or an exterior wall, which is usually a substantial distance from the modules. With a single inverter for an array of modules, the task of installing and connecting the DC conductors also presents a problem. Since the installers of the PV power generating system work on rooftops with live DC conductors, it is necessary that the crew of installers be augmented by an electrician who is knowledgeable with respect to working with potentially lethal DC voltages and also willing to work on roof tops, and also that the entire crew properly manage the safety risk posed by the DC voltages.

The problems noted above have resulted in efforts to integrate a power converter with each solar cell module. That approach is exemplified by U.S. Pat. No. 6,593,521 of T. Kobayashi, cited above. However, the Kobayashi module has limitations as a consequence of the fact that the power converter is physically secured directly to the rear surface of the PV laminate.

Other problems and limitations encountered with prior photovoltaic generating systems are specific to the frame construction of the PV modules and the means for interconnecting and mounting PV modules in an array on a roof. Problems and limitations with PV module frame construction include designs that make it uncomfortable or awkward for a person to carry or lift a module and/or that make it difficult and costly to mechanically couple modules together for improved mechanical integrity. Problems and limitations specific to PV mounting systems stem from designs that (a) make it difficult for a person to access centrally located PV modules in a roof array for inspection, repair or replacement, (b) require excessive installation labor, (c) complicate mechanical integration of adjacent modules, (d) introduce air dams that reduce airflow underneath the modules and thereby increase module temperature and reduce module efficiency, (e) make inadequate provision for cable routing, resulting in cables being exposed in position to be damaged by exposure to the environment or by workman working on the rooftop, (f) complicate electrical grounding due to the need to run a separate conductor to each component having metallic surfaces, (g) do not provide an aesthetic appeal, (h) make it difficult to replace modules; and (i) make inadequate provision for avoiding pooled water on the face of the PV modules, resulting in residual sediment that shades the PV cells when the pooled water evaporates.

### OBJECTS AND SUMMARY OF INVENTION

A primary object of this invention is to provide a PV module frame construction and PV module mounting system that integrates a substantial portion of the ultimate PV power generating system in the factory rather than at the place of installation.

A further object of this invention is to provide a PV module with a multi-functional frame construction that permits the photovoltaic power-generating cells, power conversion means, wiring and aspects of module-mounting means to be merged into the module.

Another object is to provide an improved PV module comprising a photovoltaic cell laminate surrounded at its edges by a frame, and an inverter that is carried by the frame and electrically integrated with the photovoltaic cell laminate, whereby the module and inverter coact to form an AC power-generating system.

Another object is to provide a novel PV module construction and means for mechanically and electrically coupling together two or more such modules that offers direct savings in costs and time for module manufacture and also module installation.

A further object is to provide a module construction and mounting means to facilitate mounting a plurality of PV modules on a tilted or flat roof.

Still other objects of the invention are to simplify the mechanical attachment of modules to each other and also to roofs decks/rafters, to allow for module expansion and contraction in an array of PV modules, permit adequate air flow between roof surface and PV modules, assure adequate heat transfer to dissipate heat generated by the DC-to-AC power conversion components, and facilitate electrical cable routing and electrical equipment grounding.

These and other objects are achieved by providing a PV module comprising a multi-photovoltaic cell laminate having front and rear surfaces and electrical output terminals, an inverter connected to those electrical output terminals, and a substantially rigid frame structure surrounding and overlapping edge portions of the photovoltaic laminate, with the frame comprising an integral elongate channel on its rear side for accommodating one or more electrical cables for connecting the output terminals to the inverter and also to other PV modules. The elongate channel is disposed behind the laminate and has passthrough openings for electrical cables. An inverter is mounted to the frame of each module. In one embodiment of the invention the inverter is mounted within the elongate channel, and the frame has an outer side opening for introducing the inverter to the channel, and a cover plate for concealing that opening is releasably secured to the frame. In an alternate embodiment the Inner side of the channel in the frame has an opening whereby the inverter can be attached to the frame from the underside of the module. Each module frame has integral mechanical interface means for mechanically interfacing with module support members that are adapted to be secured to an underlying building roof structure. The support members are sized to secure the PV module to a roof with the rear surface of the module spaced from the roof by an amount sufficient to permit adequate cooling air flow between the module and roof.

In the preferred embodiment of the invention the laminate is rectangular and the frame is made up of four frame members, with each of two opposed frame members having an integral interface means in the form of a captivating flange that projects outwardly and downwardly and also lengthwise of the outer surface of that frame member. The captivating flanges are shaped so as to define U-shaped channels sized to accept the upper end of one or more support members in a close fit, whereby the module can be positioned on two support members with its dead weight supported entirely by the two support members. The U-shaped channels also allow the points of engagement between the modules and its support members to be shifted in one direction or the other lengthwise of the channels as the module is being mounted on a roof, thereby allowing the module support members to be located directly over the roof rafters. Each of the two opposed frame members also has a flat groove in its outer surface that extends lengthwise parallel to its captivating flange, and each support member comprises screw means for frictionally engaging the bottom of the groove, whereby to lock the module against movement relative to the support members.

The invention also comprises mechanical connector members for releasably connecting two or more PV modules in serial and co-planar relationship, with each connector member being releasably attached to two adjacent PV modules. Electrical cables connect the inverters of the several modules, with those cables extending along the in-frame channels of the PV modules. In one embodiment of the invention those cables extend between two adjacent modules via a channel defined by one of the mechanical connector members. In another embodiment the inter-module cables pass through aligned openings in the frames of the adjacent modules. Optional features of the invention include a drainage channel in the frame for draining moisture accumulating on the front surface of the module, attaching the inverter to the cover plate so as to be removable therewith, and releasably attaching handles to a module to facilitate transporting it onto a roof and/or for positioning on the module support members.

The foregoing and other features and advantages of the invention are described in or rendered obvious by the following detailed description taken together with the drawings.

### THE DRAWINGS

FIG. 1 is a fragmentary view in elevation of a module illustrating the cross-sectional shape of one of the module's frame members.

FIG. 2 is a fragmentary view in elevation illustrating the cross-sectional shape of another of the module's frame members, with the module attached to a module support stand.

FIG. 3 is a fragmentary perspective view illustrating how the ends of adjacent frame members are mitered to form corner joints of the module's frame.

FIG. 4 is a fragmentary perspective view showing the same module attached to one of the module support stands.

FIG. 5 is a view in elevation illustrating a number of modules mounted on support stands and the resulting air space underneath the modules.

FIG. 6 is a fragmentary view in elevation, partly in section, illustrating two modules sharing a common module support stand.

FIG. 7 is a fragmentary cross-sectional view of a module illustrating how one of its frame members is adapted to house an inverter.

FIG. 8 is a bottom view of a module comprising two PV laminates, an inverter and the wiring that connects them.

FIG. 9 is perspective view of a module connector for mechanically linking adjacent modules.

FIG. 10 is a sectional view in elevation illustrating the module connector of FIG. 9 attached to a module.

FIG. 11 is a fragmentary perspective view showing two modules coupled to one another by a module connector.

FIG. 12 is a side elevation similar to FIG. 5 but showing the several modules mechanically interconnected by module connectors.

FIG. 13 is a fragmentary side view in elevation illustration how an AC electrical cable passes from one module to an adjacent module via a module connector.

FIG. 14 is cross-sectional elevation view of the interface rail that supports the two PV laminates shown in the module of FIG. 8.

FIG. 15 is a fragmentary perspective view illustrating how the end of the interface rail of FIG. 14 is shaped to interface with the frame of the module.

FIG. 16 is a fragmentary perspective view illustrating a handle member attached to the module.

FIG. 17 is a fragmentary plan view of the corner junction of two frame members illustrating a drainage gap for draining pooled water from the module's front surface.

FIG. 18 is an electrical block diagram illustrating how several arrays of AC modules are coupled together to form a higher power AC generator with suitable voltage and current parameters.

FIG. 19 is a schematic view illustrating a module's AC cable coupled to an electrical junction box by a quick connector assembly.

FIG. 20 is a schematic view illustrating how a junction box as well as an inverter can be mechanically integrated with a module.

FIG. 21 illustrates an alternate location for the junction box.

FIG. 22 is a fragmentary view relating to an alternate embodiment of the invention and illustrates a modified form of frame member.

FIG. 23 is a view similar to FIG. 22 but showing a different form of module connector and how it is secured in place.

FIG. 24 is a view similar to 7 but relates to the same alternate embodiment as the frame member shown in FIG. 22. FIG. 24 illustrates a different method of mounting an inverter to a module frame.

FIG. 25 illustrates means for altering the appearance of the interface support rails in a multi-laminate module.

FIGS. 26A and 26B illustrate how the appearance of a multi-laminate module can be altered by use of a member as shown in FIG. 25.

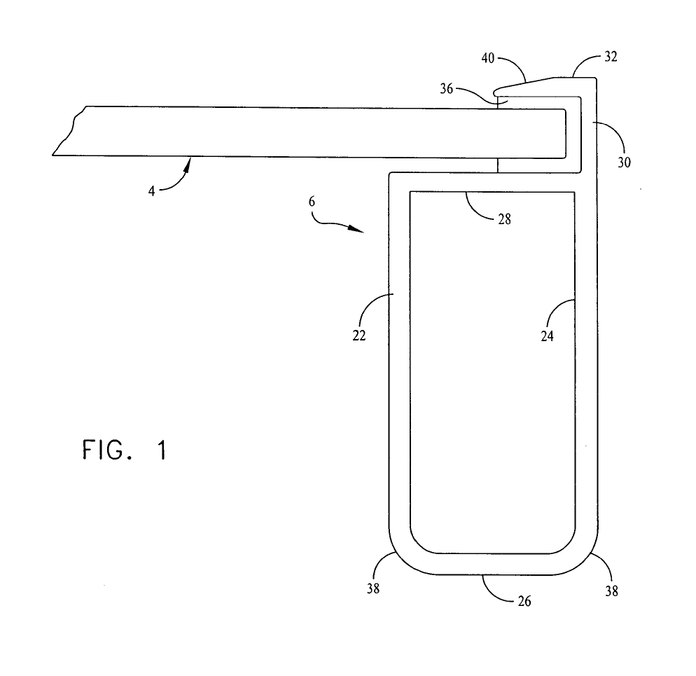

For convenience of illustration, the PV laminates are not shown in section in FIGS. 1, 2, 6, 7, 10, and 22-24.

In the several figures, like numerals identify like parts.

### DETAILED DESCRIPTION OF INVENTION

As used herein, the term “PV” is an acronym for “photovoltaic” and the term “photovoltaic power generating system” means a system comprising one or more PV modules. As used herein, the term “PV module” denotes an assembly of one or more PV laminations and a frame surrounding and supporting the laminate(s). Also a used herein the term “PV laminate” denotes and identifies an integral unit comprising a front transparent panel and a rear supporting panel, a plurality of electrically interconnected photovoltaic cells encapsulated between the front and rear panels, and electrical output means whereby the power generated by the cells can be transmitted for processing and/or use.

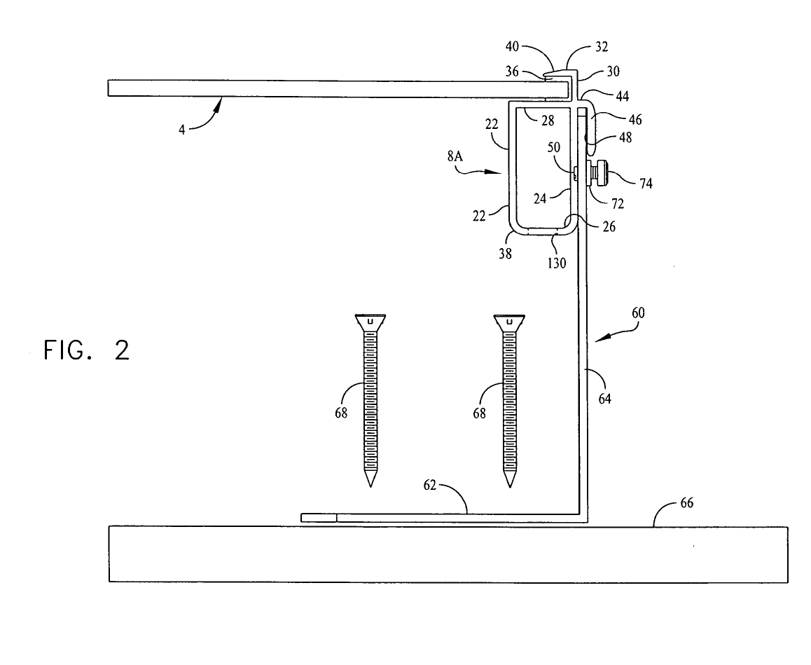

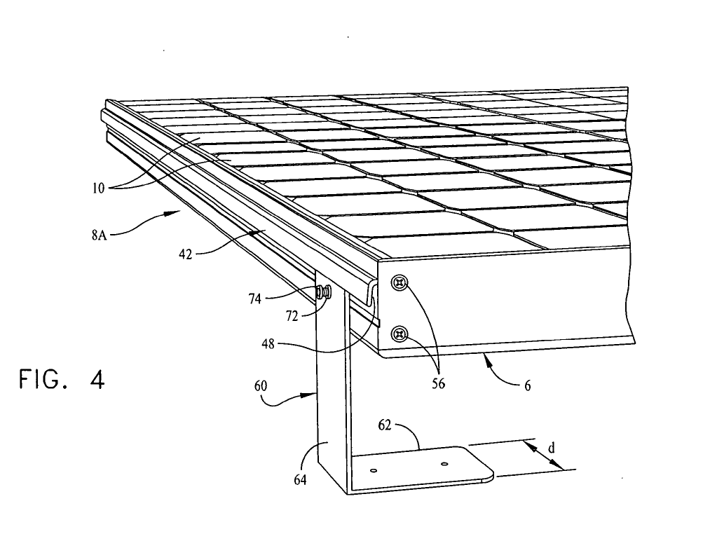

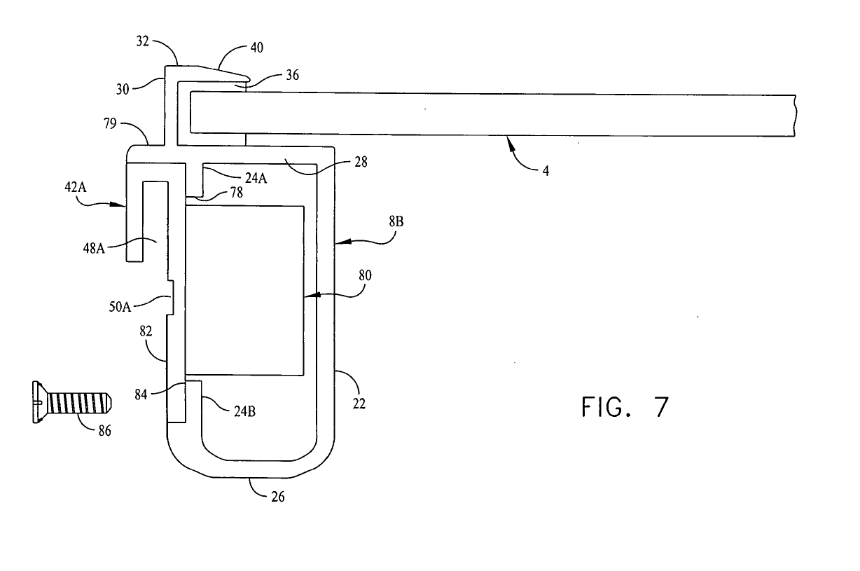

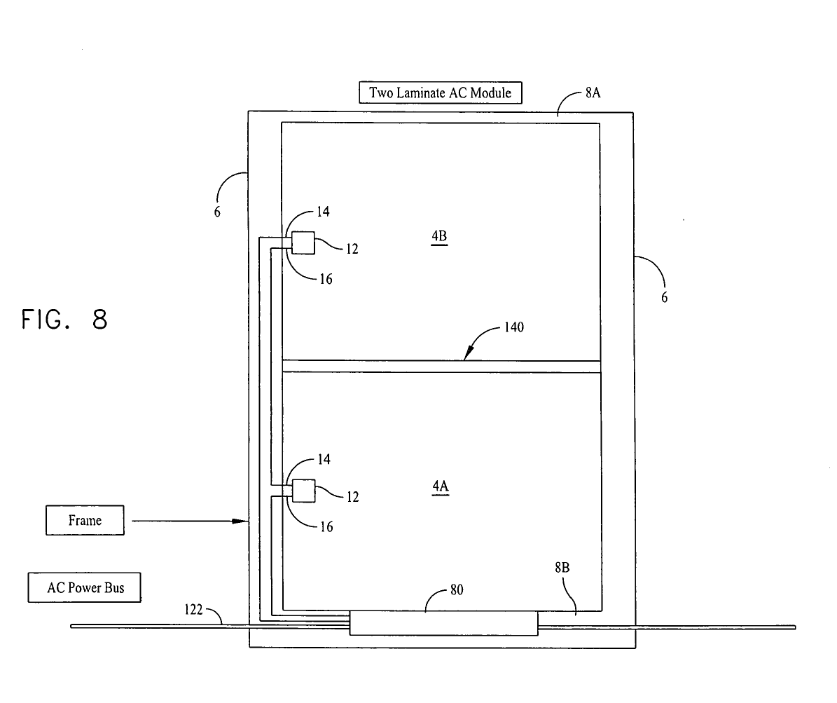

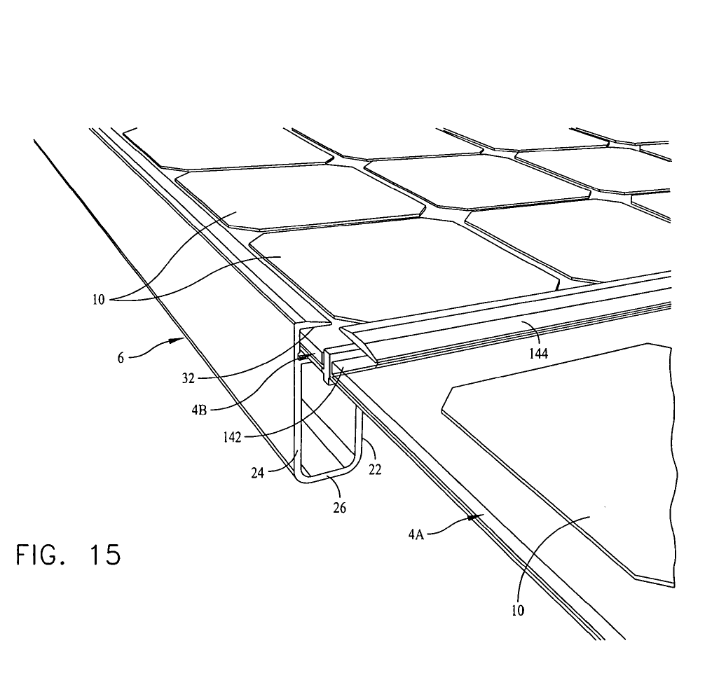

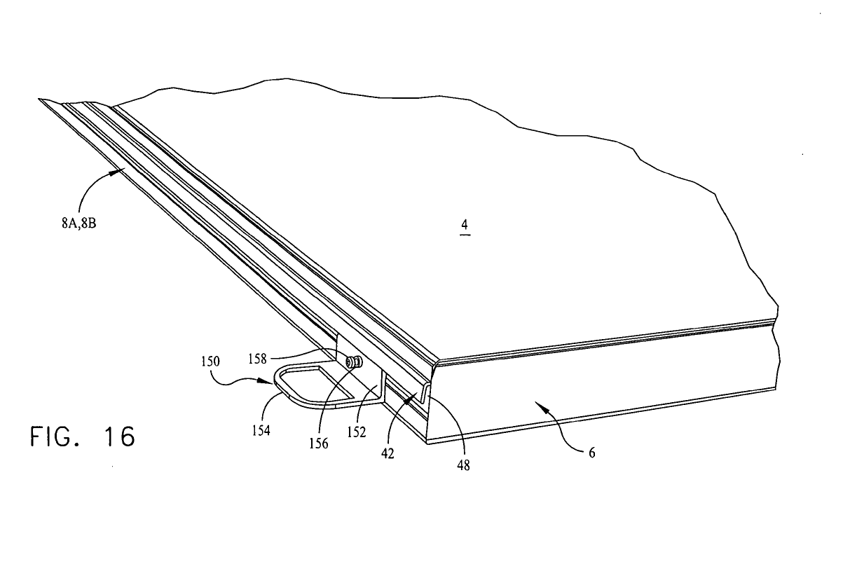

Referring now to FIGS. 1-4 and 6-8, there is shown a module that comprises one or more rectangular PV laminates 4 surrounded by a frame that comprises two opposite metal frame members 6 (FIGS. 1, 3, 4) and two opposite metal frame members 8A (FIGS. 2-4 and 6) and 8B (FIG. 7) that extend at a right angle to frame members 6. Except for FIGS. 4, 8 and 15, details of construction of the laminates are omitted since the specific construction of the laminate is not critical to the invention. In FIGS. 4 and 15 the laminate is illustrated as comprising a plurality of discrete photovoltaic cells 10 and in FIG. 8 the laminates are shown schematically as having on their rear sides a terminal section 12 from which extend two output cables 14 and 16 that carry the electrical output of the interconnected cells. Accordingly it is to be understood that various forms of PV cell laminates may be used in the practice of the invention. By way of example but not limitation, the PV cell laminates may be manufactured as disclosed by U.S. Pat. Nos. 4,499,658, issued Feb. 19, 1985 to K. J. Lewis for Solar Cell Laminates; 5,733,382, issued Mar. 31, 1998 to J. I. Hanoka for Solar Cell Modules and Method of Making Same; 5,593,532, issued Jan. 14, 1997 to J. Falk et al. for Process of Manufacturing Photovoltaic Modules; and U.S. Patent Application Publication No. US 2006/0219291 of M. Hikosaka et al. for Photovoltaic Module, published Oct. 15, 2006.

Preferably the frame members are made of aluminum, but they could be made of some other material, e.g., steel. The frame members are extrusions and, as seen in FIGS. 1, 2, 6 and 7, the frame members 6 and 8A all comprise a box channel section that consists of a pair of sidewalls 22 and 24, a bottom wall 26, and a top wall 28, and a laminate-retaining section comprising a sidewall 30 that is an extension of the sidewall 24 and a right angle flange 32. The upper surface of top wall 28 is flat and coacts with the laminate-retaining section to define a laminate-receiving channel for receiving the edge portion of the laminate 4. The laminate-receiving channel may be sized so that the edge of the laminate make a snug fit therein, but preferably a gasket or a resilient sealing compound 36 surrounds the edge of the laminate in the channel. The bottom end of the box channel section preferably has rounded corners as shown at 38 to facilitate handling of the modules by an installer.

Frame member 8A differs from frame members 6 in that it has an L-shaped captivating flange 42 comprising a horizontal section 44 projecting outwardly from the outer surface of outer box channel wall 24 and a downward extending section 46 that extends at a right angle to section 44. Sections 44 and 46 define a channel 48 (FIG. 4) of limited width. The captivating flange 42 extends for the full length of frame member 8A. Additionally, the outer surface of outer wall 24 of the box channel is formed with a flat bottom groove 50 that extends for the full length of the frame member.

As shown in FIG. 7, frame member 8B differs from frame members 6 and 8A in that it has a C-shaped channel section comprising side wall 22, bottom wall 26, top wall 28, and outer wall portions 24A and 24B that define an opening 78. The latter opening extends for the full length of frame member 8B. Preferably frame member 8B also is formed with a rib-like projection 79 on its outer side in line with top wall 28. Projection 79 also extends for the full length of frame member 8B.

An important aspect of the invention is provision of an inverter for each module, with the inverter mounted to the frame. For this purpose, and as seen in FIG. 7, an inverter represented generally at 80 is introduced to the interior of the C-channel section via opening 78. Preferably the inverter 80 is mounted to a metal cover plate 82 and the outer wall sections 24A and 24B and projection 79 together define a recess as shown at 84 to accommodate the cover plate. The cover plate is secured in place by screws 86 which are received in holes in the wall portion 24B (the size of the screws is exaggerated in FIG. 7). The holes in wall member 24B may be pre-threaded or screws 84 may be self-tapping screws. The cover plate is formed with an L-shaped captivating flange 42A that defines a channel 48A like channel 48 of member 8A and a groove 50A like groove 50. Because the cover plate is made of metal, it provides the dual function of a heat sink and also a ground connection for the inverter.

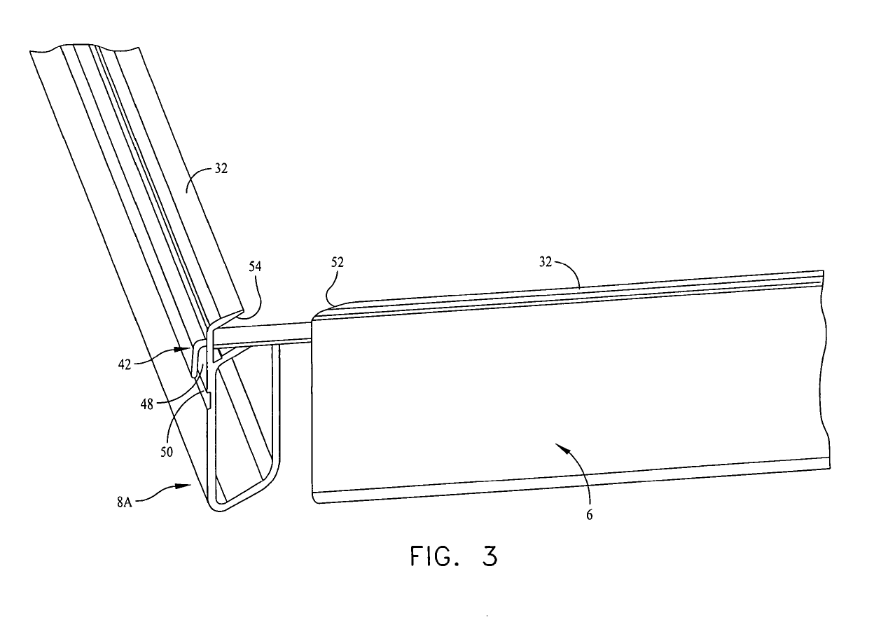

The ends of the frame members 6, 8A and 8B are cut back at an angle as shown at 52 and 54 in FIG. 3, so that when the frame members are mounted to the laminate, the opposite ends of each frame member 6 will form a mitered joint with the adjacent ends of frame members 8A and 8B. The frame members may be secured to one another in various ways, e.g., by screws 56 as shown in FIG. 4.

Referring to FIGS. 2 and 4, the modules, i.e., the laminates 4 with their surrounding frame composed of frame members 6, 8A and 8B are supported by support stands 60. At least two support stands are required for each module, with the module being supported at one side by a stand engaged with frame member 8A and at the opposite side by a stand engaged with frame member 8B. The stands are made of sheet metal, preferably aluminum, and each stand comprises a flat base section 62 and a vertical section 64 that extends at a right angle to the base section. The base section is formed with openings therein whereby the stand may be attached to a roof 66 by means of suitable fasteners, e.g., screws 68. The height of the stands and also the width (i.e., the dimension “d” in FIG. 4) may vary, but preferably the width is relatively modest, e.g., 3-8 inches. The stands are made with a sheet metal thickness sized to make a close fit in the channels 48 formed by the captivating flanges 42 of frame members 8A and 8B. Preferably the stands have a metal thickness in the range of 0.0625 to 0.25 inches.

The modules are positioned on the stands, with the upper end of the vertical section 64 of the stands extending into the channels 48 and 48A formed between the captivating lip 42 and 42A and the outer surfaces of frame member 8A and cover plate 82. The stands are sturdy enough to support the dead weight of a module. The fit of the upper ends of the stands in the channels 48 and 48A of frame member 8A and cover plate 82 is close enough to maintain the outer surface 24 of the frame members 8A and the outer surface of cover plate 82 flat against vertical sections 64 of the stands, yet not so close as to prevent an installer from shifting the module fore and aft, i.e., in a direction parallel to the lengthwise axis of the captivating flanges 42 and 42A, as may be deemed necessary for proper alignment of the module relative to other modules forming part of an array. Means are provided for securing each module to its supporting stands once the module has been properly positioned on the stands. For this purpose the vertical section of each stand 60 is provided with a hole in which is fixed a threaded bushing 72 that receives a set screw 74 having a shank which is sized to enter groove 50 in the adjacent frame members 8A or 8B and make tight contact with the flat bottom surface of that groove. The set screws tend to bite into the aluminum frame members and thereby lock the module against the fore and aft movement described above.

The PV modules and mounting stands herein described are intended to be mounted on an inclined roof, preferably one that faces in a southerly direction. It is preferred that the modules be oriented so that frame members 8A and 8B extend horizontally on the inclined roof and the frame members 6 are inclined at the same angle as the roof. Also it is preferred that each module be mounted so that its frame member 8B forms its bottom edge, thereby making it easier to access the inverters which are located on those frame members.

It is contemplated that the modules will be arranged in rows and columns in an array on a roof. Accordingly the module frame and mounting system incorporates provision for (a) mechanically interconnecting all of the modules in a multi-module array so that the modules essentially reinforce one another and thereby form a stronger and more stable structure on a roof, and (b) routing and housing electrical cables that interconnect the modules.

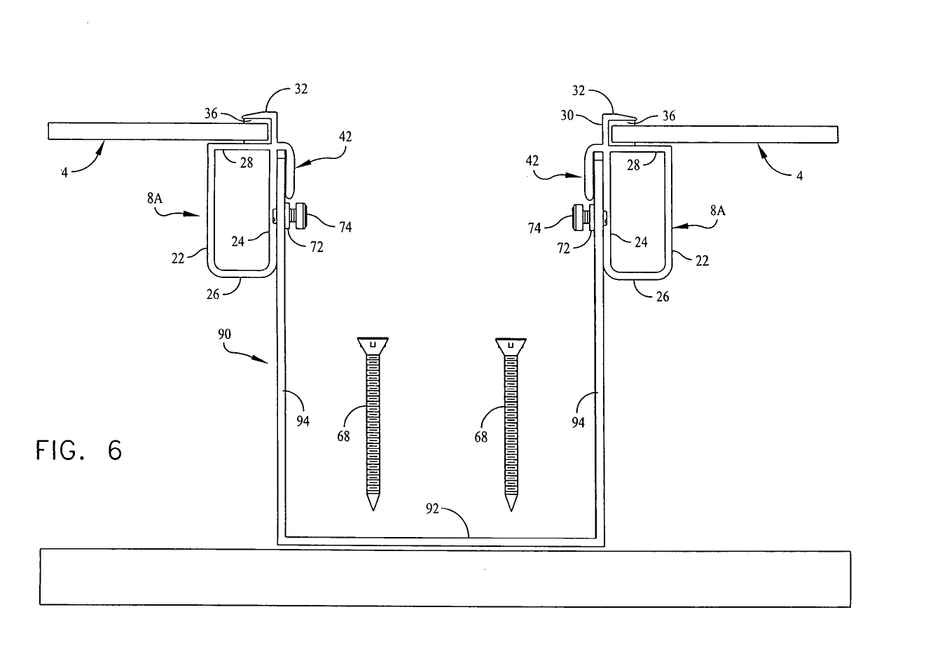

Referring now to FIG. 6, mechanical interconnection of modules along one axis, e.g., as a column of modules, is accomplished by providing and using a plurality of dual stands 90 comprising a common base section 92 and a pair of vertical sections 94. Each of those vertical sections is intended for supporting engagement with two frame members 8A or 8B of adjacent modules. FIG. 6 shows the dual stand engaged with like frame members 8A of two adjacent modules, but it is to be understood that depending on the orientation of the two modules relative to one another, the two vertical sections 94 could be engaged with and support two like frame members 8B, or one frame member 8A and one frame member 8B. The dual stands provide automatic spacing of the modules in the column. While the dual stands 90 may be used to support all of the modules in an array, they may be replaced by the mechanical stands 60. Alternatively the stands 60 could be used to support modules only at the opposite ends of each column of modules in a column and row arrangement of modules.

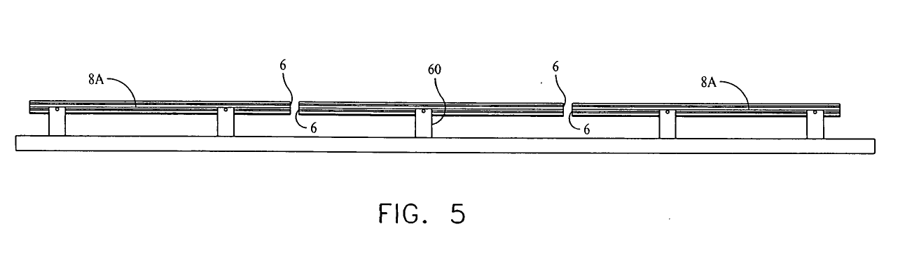

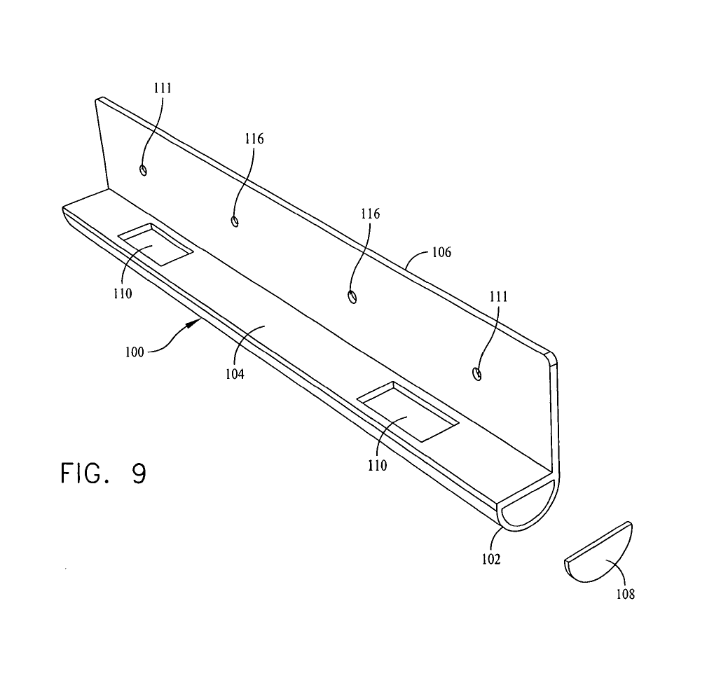

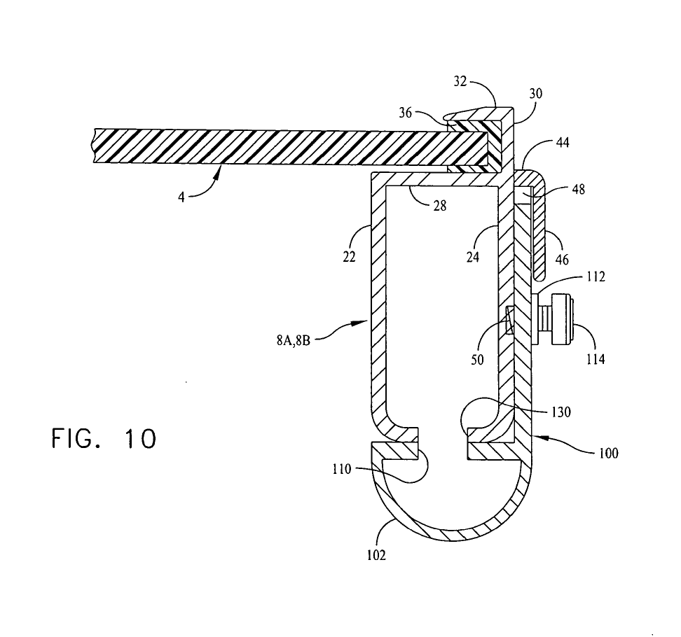

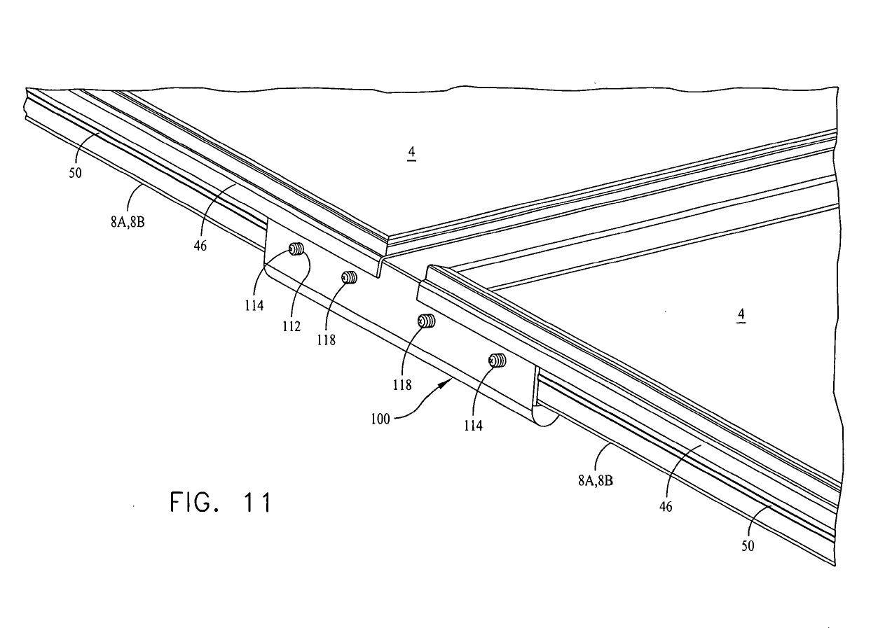

Referring now to FIGS. 5 and 9-13, the invention also provides for connecting modules aligned along a second axis at right angles to the first axis mentioned above, i.e., as a row of modules. As shown in FIG. 5, the modules are mounted spaced in relation to one another in each row, i.e., with adjacent modules having their frame members 6 in spaced confronting relationship with one another. FIG. 9 illustrates a mechanical connector member or link 100 designed for this purpose. Two such connector members are used to connect two adjacent modules, one on each of the two opposite sides of the module frames that are characterized by frame members 8A and 8B. Each connector member comprises a channel section 102 that preferably, but not necessarily, has a semicircular cross-section as shown, and comprises a flat wall 104. The connector member 100 also has a projecting plate section 106 that extends at a right angle to wall 104. It is to be noted that the opposite ends of the circular channel are closed off by end caps 108 that preferably are removable. The wall 104 is provided with a pair of mutually spaced openings 110. Additionally, plate section 106 has two holes 111 in which are threaded bushings 112 (FIG. 10) that receive set screws 114. Two additional holes 116 are also formed in plate section 106.

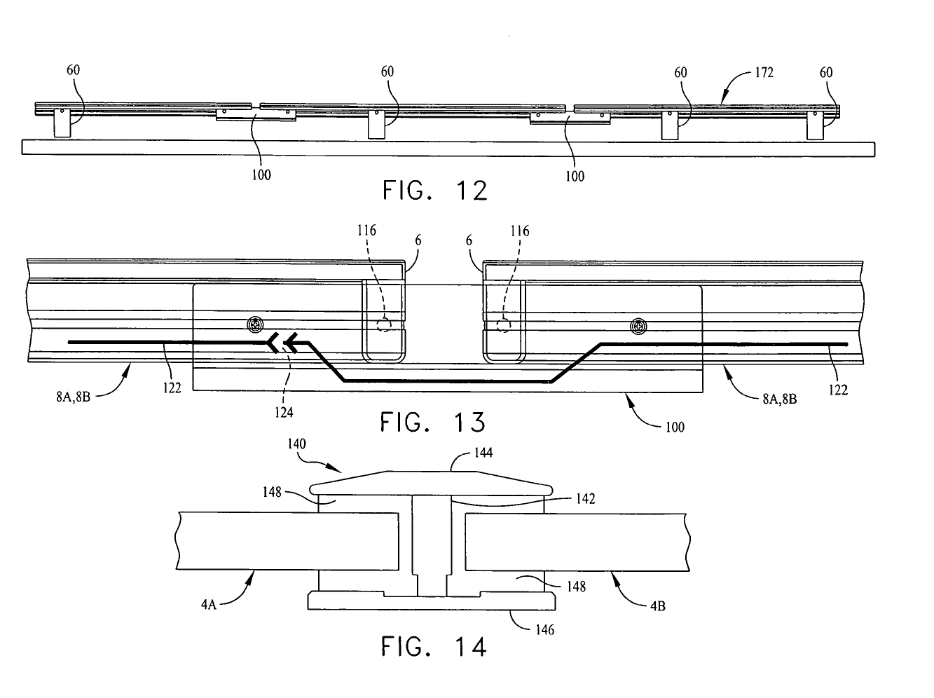

Each connector member 100 is positioned between and overlaps the side frame members 8 (A or B) on one side of adjacent modules, with the plate section 106 of each connector member disposed within the channels 48 and 48A formed of those frame members. Bushings 112 are positioned so that screws 114 will extend into the grooves 50 and 50A of frame members 8A and cover plate 82 and make a tight grip with the bottom surface of those grooves, whereby to lock the connector member to the two adjacent modules. The other holes 116 are positioned so as to be aligned with the mutually confronting frame members 6 of adjacent modules. Screws 118 (FIG. 13) may be inserted through holes 116 and driven into the mitered corner end portions of frame members 8 and the frame members 6 that are attached to frame members 8, thereby securing the connector member to both modules. Screws 118 may be self-piercing, self tapping screws or the mitered corner portions of the modules may be provided with threaded holes. Attaching two connector members 100 to two adjacent modules as above described creates a strong mechanical connection between the modules. Preferably each module is provided at the factory with a multi-wire electrical cable 122 that functions as an AC power bus. The cable is connected at one end to the inverter.

A primary function of the box and C-channel sections of the frame members is to provide a passageway for the cables that interconnect the modules and the inverters, as well as an AC power bus that links all of the modules in an array. This function is illustrated schematically by FIG. 8 which also illustrates how a module may consist of more than one PV laminate. For convenience, the four sides of the module are identified by the numerals used hereinabove to identify the four frame members. FIG. 8 is a schematic bottom view of a module comprising two laminates 4A and 4B in side-by-side relation with one another. Each of the laminates has a terminal section 12 and two cables or lead wires 14 and 16 that carry the DC output from the laminates. Those cables are connected to inverter 80, being routed into the interior space of the channel section of one of the frame sections 6 and then into the interior space of the channel section of the frame member 8B that also contains the inverter. The inverter in turn is connected to an AC power bus cable 122 that extends within the frame and also connects to the inverters of other modules. Preferably each module is pre-wired at the factory with a multi-wire electrical cable that is connected to its inverter 80 and is adapted for connection to the like cable of an adjacent module by a quick-connector 124 (FIG. 13), thereby forming the bus 122.

Referring now to FIGS. 2 and 10, the routing of cables is facilitated by providing holes 130 at selected locations in the bottom walls of the channel sections of the frame members 6 that carry the DC cables from the PV laminate(s) and also in the bottom wall of the channel sections of the side frame members 8A and 8B for transitioning cables through the channels of the connector members 100. Referring also to FIG. 13, the illustrated power bus cable 122 that interconnects the inverters of the modules in an array extends within the channels of the side frame members 8A or 8B and also extends within the channel provided by each connector member 100, passing into and out of the connector member channel via holes 130 in the frame members and openings 110 in connector members 100 so as to bypass the mutually confronting end frame members 6 of the connected modules. Making end caps 108 removable is helpful in routing the cables into and out of the channel sections of connector members 100. It is believed obvious that the foregoing frame and frame connection construction effectively assures that the electrical cables and also the inverter are isolated from the elements since they are contained within the channels provided by the module frames and module frame connectors.

Referring again to FIG. 8 and also to FIGS. 14 and 15, the module may consist of only one laminate or more than one laminate. In the case of having more than one laminate in a module, it is advantageous to physically support adjacent portions of the laminates. FIG. 8 shows an interface support rail 140 disposed between the two laminates 4A and 4B. The support rail comprises a central web section 142 and top and bottom laminate-retaining sections 144 and 146, with the spacing between retaining sections 144 and 146 being sized to make close fit with the adjacent edge portions of the two laminates (the spacing between the laminates 4A and 4B and rail 140 is exaggerated in FIG. 14). Having the interface support rail in place improves resistance to deflection of the laminates under wind or other forces. As shown in FIG. 15, the ends of sections 144 and 146 are cut back to make a close joint with the edges of the flange 32 of the laminate-retaining section of the adjacent frame member, while the end of center web section 142 extends into and make a tight fit with laminate-receiving channels of frame member 6. If desired, a gasket 148 or an adhesive sealing compound may be interposed (in the manner of the gasket 36, in FIG. 1) between the edges of the laminates and the laminate-retaining sections 144 and 146 to protect those edges against deterioration from environmental factors.

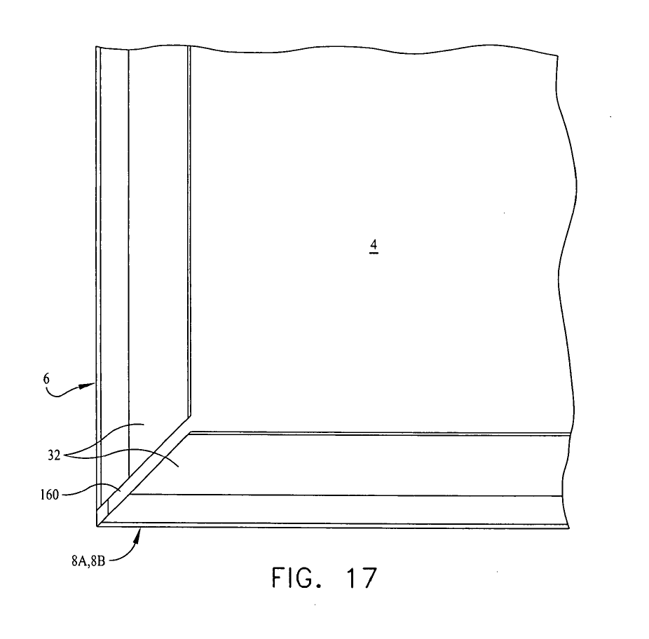

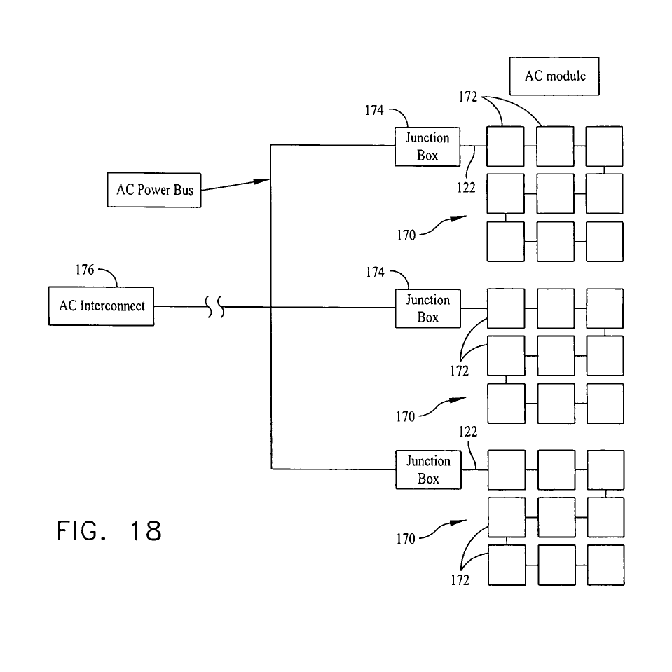

Additional aspects of the invention are illustrated in FIGS. 16 and 17. In FIG. 16, a module-hoisting handle member 150 is provided for attachment to the side frame members 8A and 8B. Member 150 consists of a flat plate section 152 that extends up into the channel 48 formed by captivating flange 42 and make a close fit in that channel, and a right angle ring section 154 that serves as a handle. Plate section 152 has a hole in which is fixed a threaded bushing 156 that accommodates a set screw 158 is sized to fit in the groove 50 and make a locking connection with the frame member. One or more such handles may be mounted to one or both of the opposite side frame members 8A and 8B, depending on the size of the modules and number of individuals needed to lift and transport the module. The handles may be removed after the modules are installed.

FIG. 17 relates to the problem of moisture condensing on the front panel of the laminate. It has been determined that moisture condensing on the front panel will eventually evaporate, leaving sediment that will shade the cells and thereby reduce overall energy conversion efficiency. With the module mounted at an inclined angle on a roof, water will pool at the lower edges of the module, with the result that on evaporation the lower cells will be the ones that are adversely affected by the resulting sediment. This problem is eliminated or greatly alleviated by cutting back the mitered ends of one or both of adjacent frame members 6 and 8. Assuming that the modules are to be mounted at an inclined angle with their frame members 8A and 8B extending horizontally, at each of the two lower corners of each module the laminate-retaining section comprising side wall 30 and laminate-retaining flange 32 of frame member 6 is cut back a short distance from the adjacent frame member 8A or 8B so as to provide a drainage gap 160. Since the modules are mounted at an inclined angle, water collecting at the lower end of the module can rapidly drain away via the drainage gaps, thereby reducing the likelihood of residual sediment shading the lower cells of the module.

The power output bus 122 of an array of PV modules will be connected to an electrical junction box to facilitate maintenance and repair as well as its connection to other electrical system components, e.g., system monitoring, measuring, recording and control devices, as well as to the power grid of a public utility. Referring now to FIG. 18, it is contemplated that in the case where a photovoltaic power generating system consists of two or more arrays 170 of modules 172, each array will have its own junction box 174, and those boxes in turn will be connected to an AC interconnect 176 where the total power output of all of the arrays is collected, monitored and transmitted for ultimate consumption on site or via a utility power grid. The individual junction boxes 174, and preferably also the AC interconnect 176, will include switches whereby individual arrays may be taken off line for safe inspection and repair.

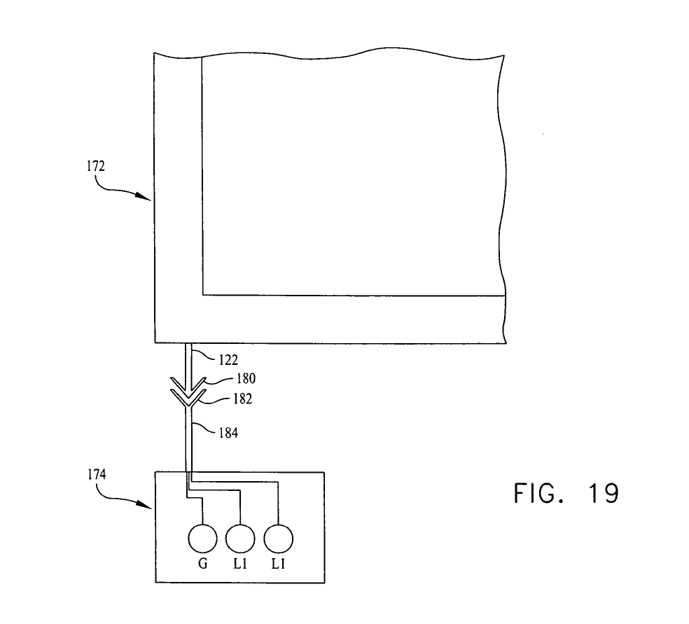

Referring now to the schematic representation of FIG. 19, according to one embodiment of the invention the AC power bus from each array is provided with a connector member 180 that mates with a second connector member 182 attached to a cable 184 connected to the array's junction box 174, and that junction box is mounted away from the array, e.g., directly to the roof on which the array is mounted or inside the building. Preferably connector members 180 and 182 are parts of a quick-disconnect connector apparatus.

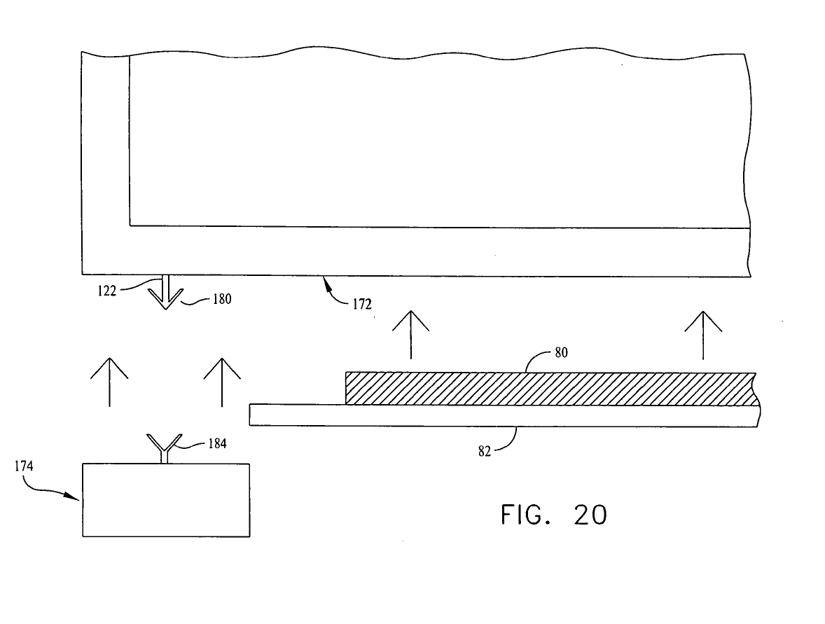

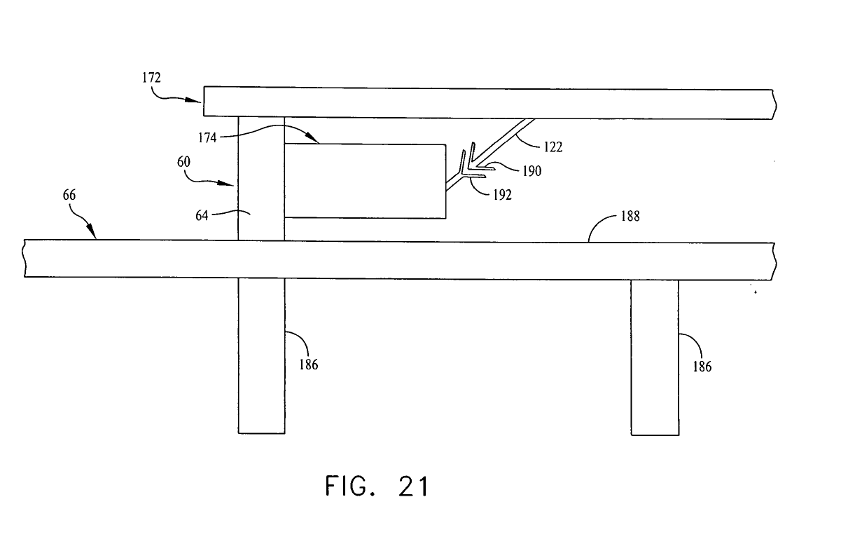

FIGS. 20 and 21 schematically illustrate alternative arrangements for mounting junction box 174. In FIG. 20, a connector member 180 is mounted in an opening in frame member 8B proximate to where the inverter 80 and cover plate 82 are located, and the junction box 174 is provided with a mating connector member 182 that mates with connector member 180. The mating connector members may be designed to secure the junction box in place, or the box may be secured to frame member 8B by screws or other means. FIG. 21 shows a roof 66 comprising rafters 186 and a roof top 188, with a module support stand 60 attached to the roof top and with the junction box 174 attached directly to that stand's upright section 64. In this case, the AC bus 122 passes out of hole in the module's frame and is connected to the junction box via mating connector members 190 and 192.

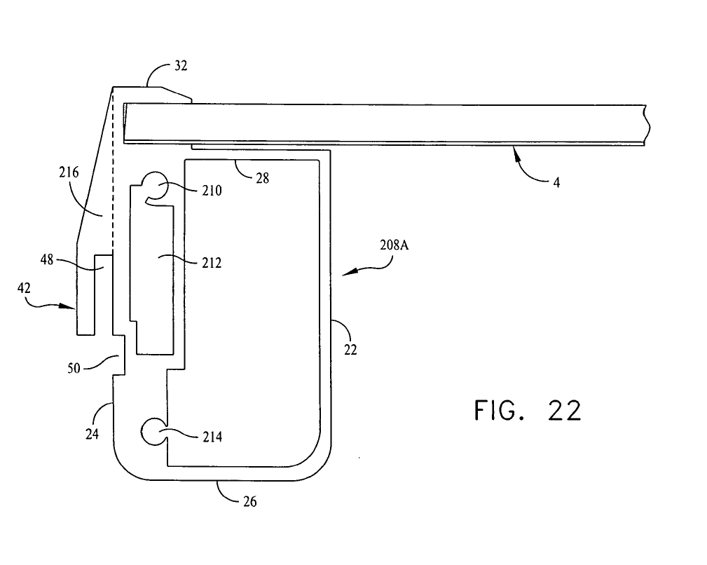

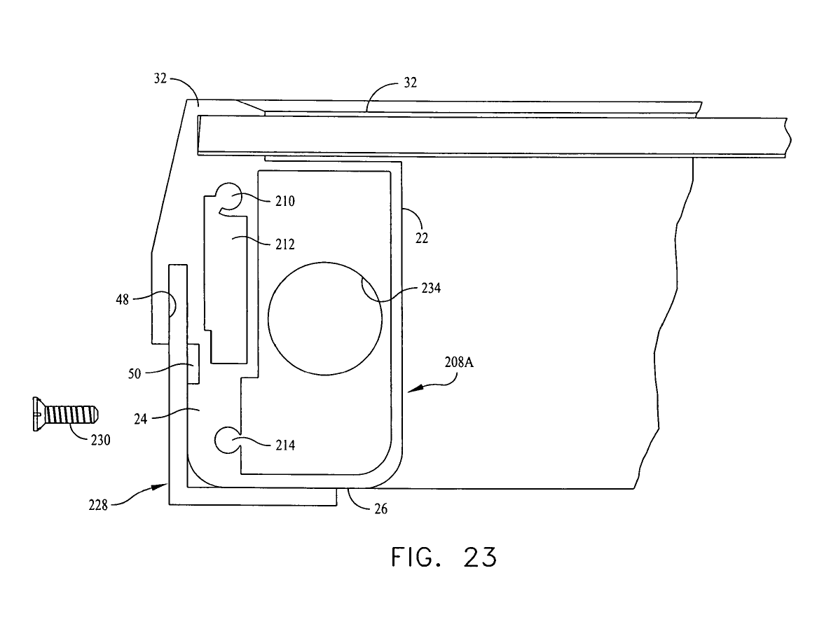

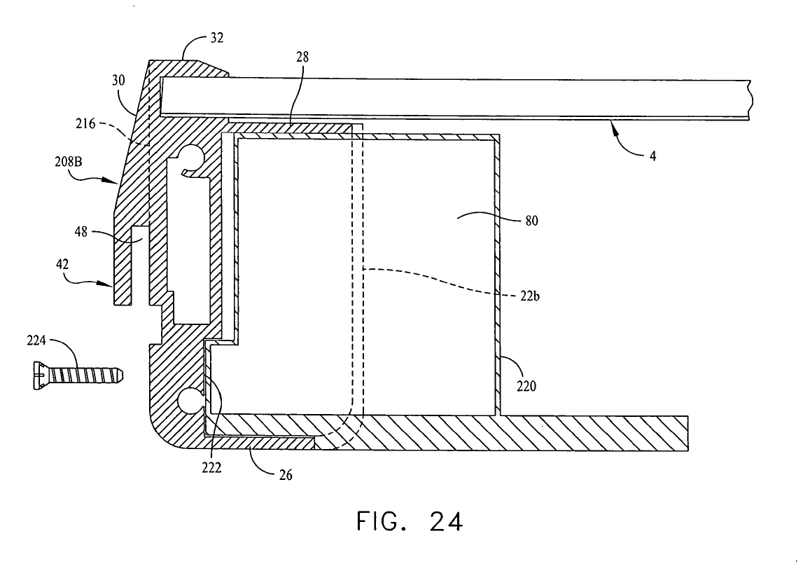

FIGS. 22-24 illustrate a modified and preferred frame member design. The frame members shown in FIGS. 22-24 may be made of aluminum and, like those shown in FIGS. 1-3 and 7, may be manufactured by an extrusion process. FIGS. 22 and 23 illustrate a frame member 208A corresponding in function to frame member 8A, while FIG. 24 illustrates a frame member 208B that corresponds in function to frame member 8B. Like the frame members shown in FIGS. 2 and 7, frame members 208A and 208B have captivating flanges 42 that define a narrow channel 48 for receiving the upper end of a mounting stand like the ones shown in FIGS. 4 and 6. However, the overall thickness of the outer wall 24 of the box channel sections of members 208A and 208B is greater than that of the outer walls 24 of the box channel sections of frame members 6 and 8, and the captivating flange is formed by cutting channel 48 into the thicker outer wall 24. A further difference is that, in comparison with the frame members shown in FIGS. 1-3 and 7, the captivating flanges 42 of frame members 208A and 208B are located lower in the frame member, with the top of channel 48 being close to the midpoint between the top and bottom sides of the frame members. A further difference is that frame members 208A and 208b also have several cavities 210, 212 and 214 for the purpose of reducing module weight and also the amount of metal used to make the frame members. Further referring to FIGS. 22-24, the frame members corresponding to frame members 6, i.e., frame members that lack captivating flanges 42, are not shown in detail, but one of them is represented generally at 206 in FIG. 23. The frame members corresponding to frame member 6 are achieved by using an extrusion die that is designed to provide an outer surface for the outer wall 24 that extends along the dotted line 216, i.e., so that captivating flange 42 and the portion of the outer wall to the left of line 216 are omitted.

Referring to FIG. 24, the frame member 208B differs from frame member 208A in that it lacks all of inner wall 22 and has only portions of lower wall 26 and top wall 28 of the box channel section of frame member 208A, all for the purpose of accommodating a housing 220 for an inverter 80 that fits between the upper and lower wall sections as shown. Preferably the inner side of outer wall 24 is notched as shown at 222 to accept a projecting portion of housing 220. The housing is secured in place by one or more screws 224 that pass through openings in outer wall 24. The absence of inner wall 22 and portions of lower wall 26 and upper wall 28 may be for the entire length of frame member 208B, but preferably those walls are absent along only a portion of the length of frame member 208B, thereby leaving portions of the box channel intact and available to contain the DC wires and the AC bus. More specifically, frame member 208B may be formed with walls 22 and 26 intact, i.e.; as shown in FIG. 23, and subsequently portions of those walls may be removed to form an opening of limited size to accommodate inverter 80 and its housing 220. The removed portions of walls 22 and 26 are shown in phantom at 226 in FIG. 24.

Referring to FIGS. 22 and 23, with the improved frame design adjacent modules can be mechanically attached to one another by using a connector member similar to the one shown in FIG. 9 and providing holes like holes 130 (FIG. 10) in the bottom walls of frame members 208A and 208B. Preferably, however, frame members 208A and 208B of adjacent modules are connected together by an L-shaped connector 228 that fits in the channel 48 and extends under bottom wall 26 of the box channel section. Connector 228 has two openings (not shown) to accommodate self-piercing, self tapping screws 230 that are driven through holes in the connector into the outer walls 24 of the two-frame members 208A and also 208B. With this connector arrangement, an opening 234 is required to be formed in the outer wall of adjacent frame members 206 in line with the interior space of the box channels of frame members 208B, so that the AC power bus can pass between adjacent modules.

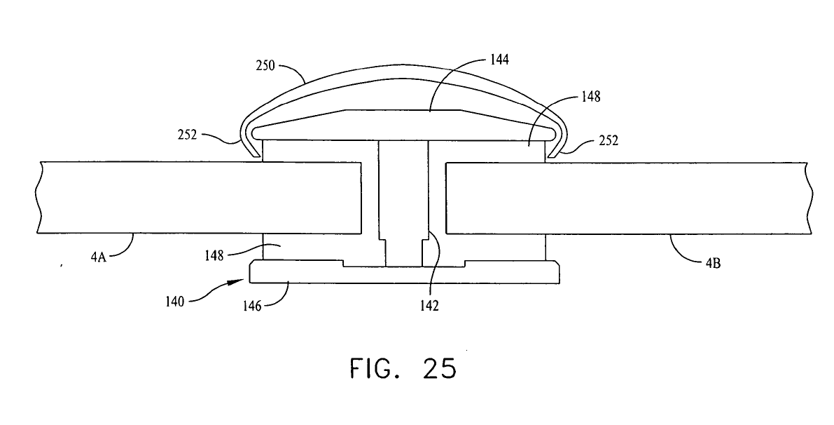

Referring back to FIG. 8, as described above interface rails 140 are used to support adjacent PV laminates in a rectangular module. The rectangular module may be square or it may be longer in one direction than the other. The same is true of the PV laminates. Thus in FIG. 8, both the PV laminates and the module frame have a non-square shape, with the PV laminates oriented to present a landscape image and the module presenting a portrait image. The surrounding frame consisting of frame members 6, 8A and 8B usually has a color different from the front surface of the PV laminates. Typically the frame is black. Assuming that the frame is a different color than the PV laminates, if the interface rail is made with the same color as the frame, then the aesthetic effect is to see the two PV laminates demarcated by the frame and the interface rail. However, it may be desirable not to see the two laminates demarcated by the interface rail 140. In such case, the invention contemplates covering the interface rail with a member having a color that substantially matches the color of the front surface of the PV laminates. That member may take the form of a tape (not shown) that has substantially the same color as the PV laminate and which is adhesively bonded to and covers the front side surface of the interface rail. However, referring now to FIG. 25, a preferred approach is to use a separate elongate cover member 250 that is made of plastic or metal. The opposite edge portions of cover member 250 are bent back as shown at 252 so that those edge portions can extend around the opposite longitudinal edges of the upper section 144 of interface rail 140. Cover member 250 can be made with a resiliency sufficient to permit it to be snapped over and tightly grip the opposite edges of section 144 of rail 140 so that it will remain in place under varying environmental conditions.

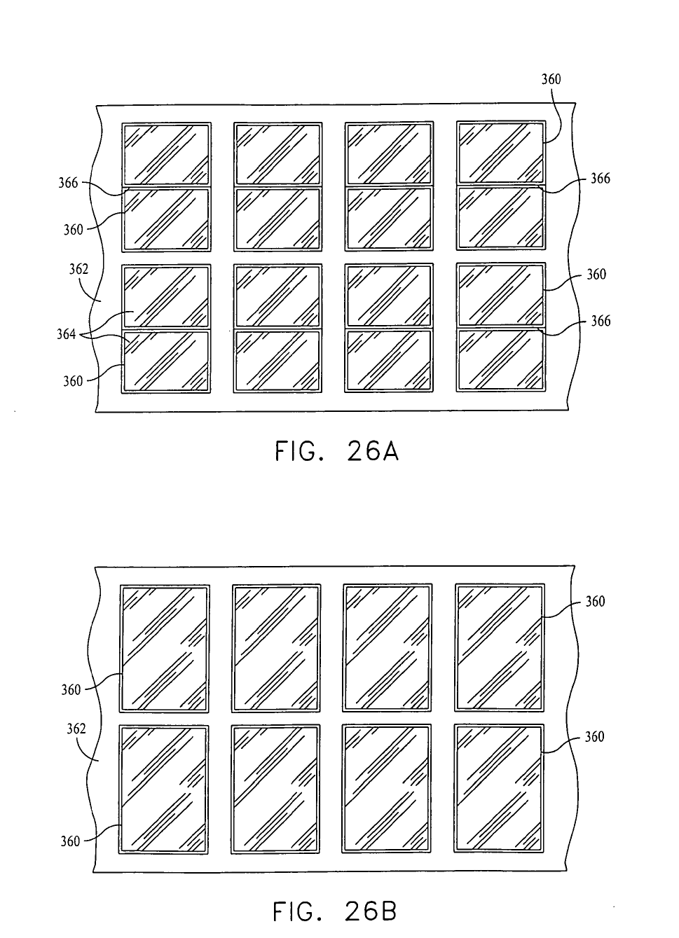

FIGS. 26A and 26B illustrate the aesthetic affect resulting from application of a like color cover member to the interface rails. FIG. 26A is a plan view of an array of individual PV modules 360 mounted on a roof 362. The array is made up of 8 PV modules 360, with each module comprising 2 PV laminates 364 separated by an interface rail 366 similar to interface rail 140 described above. Rail 366 has a color different than the upper surfaces of the PV laminates. The image presented by FIG. 26A suggests that the array consists of 16 relatively small modules having a partial orientation, i.e., the PV laminates 364 appear as 16 separate modules. If now cover members 250 are applied to the interface rails, with the cover members being long enough to fully cover the interface rails and having substantially the same color as the front surfaces of the PV laminates, the aesthetic appearance of the array will change to provide an image as seen in FIG. 26, where the array appears as 8 relatively large modules having a landscape orientation.

The invention is susceptible of a number of modifications. Thus, for example, the flanges 32 may be provided with a textured upper surface as shown at 40 in FIG. 1. Textured surfaces make it easier for an installer to grip the modules. The frame members 6 and 206 may have the same construction as frame members 8A and 208A respectively, and the cross-sectional size of the frame members may changed to modify the size of the interior channel defined by the box walls 22, 24, 26 and 28. Also the orientation of modules in an array may be changed, with the frame members 6 extending horizontally on the roof. It is also obvious that although the invention as described herein relates to modules for installation on an inclined roof, the support stands 60 and 90 could be modified so as to provide for mounting the modules at an inclined angle on a flat roof or other substrate, e.g., a concrete platform on the ground.

It should be noted that the spacing between the frame members 6 or 206 of adjacent modules connected by connector members 100 or 228 can be varied by changing the length of the connector members. Similarly, the spacing between the frame members 6 of adjacent modules can be varied by changing the spacing between stands 60 or by varying the width of the base portion of stands 90. Having gaps between modules in adjacent rows and/or in adjacent columns as shown in FIG. 18 is of value from the standpoint of improving air flow over the modules and also because the gaps may be wide enough to define a walkway on the roof for purposes of inspecting, repairing or replacing individual modules.

Another contemplated modification is to make the frame members out of plastic instead of metal. Plastic frame members can be manufactured with box and C-channel sections similar to the channel sections of frame members 6, 8A, 8B, 208A and 208B and they offer the advantage that they do not need to be grounded. With reference to FIG. 8, another possible modification it to make a module consist of more than two PV laminates, e.g., eight PV laminates arranged end to end in a single row or two rows. In the case where each module consists of two or more rows of laminates with each row consisting of two or more laminates, the module will have first and second sets of interface rails, with the rails in the first set running at a ninety degree angle to the rails in the second set.

With respect to frame member 8B, the metal cover plate may extend lengthwise of the frame member for only a limited distance sufficient to conceal inverter 80, and the remaining portion(s) of opening 78 may be concealed by an auxiliary cover plate (not shown) that may but need not be made of metal. Having a cover plate that is of limited length facilitates its removal for access to the inverter.

Another possible modification of the invention is to employ laminates of the type where the terminal leads 14 and 16 are brought out of a side edge of the laminate. In such case the frame members may be modified to provide openings at their upper walls 28 whereby the terminal leads can pass into the interior space of the channel sections.

Other possible modifications are to employ stands of different constructions. For example, the upper ends of vertical sections 64 of support stands 60 could have a U-shaped cross-section so as to define a channel for receiving captivating flanges 42. Still other modifications will be obvious to persons skilled in the art.

As is believed evident from the foregoing description, the above-described multi-function frame and mounting system has a number of advantages. For one thing, the rounded corners 38 (FIG. 1) of the channel members facilitates manually gripping the modules for transporting and lifting. A further advantage is that the channel support structures provide substantial mechanical integrity when a plurality of modules are mounted on a roof and interconnected in the manner herein described and illustrated. Mounting the modules by having the upper ends of the support stands 60 and 90 received in the narrow channels found by captivating flanges 42 facilitates locating the module supports over roof rafters as shown in FIG. 21 for more adequate anchoring to the roof structure. Being made of sheet metal, the module supports 60 and 90 have a narrow profile and thus leave an open path for airflow beneath the modules. The ratio of the height of the frame member to the air gap between the roof surface and the bottom of the frame member may be the “golden mean”, or approximately 1.618, to achieve an aesthetic balance.

An additional advantage is that the supports may have a different construction and be made in different lengths or adjustable in length. In any event, the supports can be modified as necessary to conform to statutory or building code requirements. The fact that the module frame members have captivating flanges 42 is advantageous since those flanges allow a module to be hung on the module support members pending proper positioning, after which the set screws 74 are tightened in groove 50 to prevent the module lifting off of or shifting laterally relative to the module support. The set screw 74 may be made with a pointed end whereby it can bite into the aluminum frame member to increase friction between the module frame and the module support and thereby lock the module to frame members 8A and 8B. This mode of attaching the modules to their support stands also allows for expansion and contraction of the modules.

As noted above, an array of modules is placed on an inclined roof with the frame members 8B containing the inverters being on the bottom side, in the same orientation as indicated in FIG. 8. Because adjacent modules are interconnected, modules located inwardly of the ends of each row, may be supported by a single support stand on each opposite side, while the endmost modules, e.g., module 172 in FIG. 12, may require two mounting supports 60 on each of the opposite sides of the module to assure adequate anchoring. The metal cover plates 82 and the frame members 8B and 208B to which the inverters are mounted function as a heat sink, so that any heat generated by the inverter is quickly and effectively dissipated to the environment. Since they are made of metal, cover plates 82 and frame members 8B and 208B also provide an electrical ground connection for the inverters.

As described and illustrated herein, the modules are mounded on an inclined roof with a well-defined space between the module and the roof. Because the modules heat up in the sun, and heat the air behind them, a natural convection air stream will form between the modules and the roof. The air behind the module becomes increasingly hotter as it flows toward the upper horizontal edge of the module. Therefore the coolest air running along the back of the module is at the bottom edge of the module. At the bottom edge air is drawn from the surrounding outside air and is roughly the temperature of the ambient air around the roof. The inverter is mounted in the frame member 8B or 208B that forms the bottom edge of the module, with at least one side exposed along that edge, either via cover plate 82 or via the housing 220, both of which function as a heat sink to conduct heat away from heat-generating parts of the inverter. All three exposed sides of the bottom frame member will experience some air cooling from the natural convection. However, its bottom wall 26, closest to and facing the roof, will have air flow along its entire surface, thereby maximizing its heat transfer. In an array of modules, the air flow from the ambient air will be influenced by the row-to-row spacing. Thus, for example, we have found that to achieve ambient air flow with several rows of modules the spacing between rows of modules that measure seventy-two inches tall should be at least three inches with modules four inches off the roof and a module frame that is two inches thick. Other combinations of these parameters may change the minimum row-to-row spacing.

Another advantage is that safety and long life are assured by virtue of the fact that the cables are routed inside the frame members, so that danger of injury to a person through access to DC voltages is eliminated. Additionally, the system is esthetically feasible since there are no visible wires. A further advantage of the system is that the modules may be preassembled at the factory with the wiring and inverter attached and connected as herein described, thereby reducing the time required to install a plurality of modules on a roof and to connect them for power generation. Since the cabling and the inverter reside within the module frame, the modules containing those components may be stacked on top of one another for shipping and warehousing purposes. Additionally, having handle members attached to the frame further facilitates handling of the modules. Another advantage is that the modules provide adequate drainage by virtue of the drainage channel provided at one or more of the lower corners of a mounted module. Unlike water evaporated off of the bottommost portion of the module, drained water will carry with it any dust and sediment that may otherwise result in a lower system output. Still also of value is the fact that the junction box may be mounted directly to the frame or to one of the module supports.

Still other advantages are that the modules may be made in different sizes, and the aluminum or plastic frames may be finished or manufactured in different colors to improve esthetics.

Other features and advantages will be obvious to persons skilled in the art.

1. An AC PV module comprising:
a photovoltaic laminate having DC electrical output terminals;
a substantially rigid frame surrounding and overlapping edge portions of said photovoltaic laminate, said frame comprising a plurality of interconnected frame members, with at least one of said frame members being made of a heat-conductive metal and defining an elongate channel extending parallel to an edge portion of said photovoltaic laminate;
an electrical inverter having an input section and an output section with said input section connected to said DC electrical output terminals, said inverter intruding into said channel and being mounted to and in heat-conducting relation with said one frame member; and
an AC bus connected to said output section of said inverter, said AC output bus being disposed within and extending along said channel and having at least one end projecting out of said module for connection to another module or some other electrical apparatus.

2. An AC PV module according to claim 1 wherein said photovoltaic laminate has front and rear surfaces, and said elongate channel is disposed behind said rear surface.

3. An AC PV module according to claim 1 wherein said inverter comprises a heat-conductive metal housing in heat-conducting contact with said one frame member.

4. An AC PV module according to claim 1 wherein said channel is a box channel, and further wherein said box channel has an opening for permitting access to the interior of said channel, said opening and said inverter being in substantial alignment with one another, and further including a metal cover plate releasably secured to said box channel in position to close off said opening, said frame and said cover plate functioning as a heat sink and/or electrical ground path for said inverter.

5. An AC PV module according to claim 4 wherein said inverter is attached to said cover plate.

6. An AC PV module according to claim 1 wherein said one frame member defining said channel comprises a top wall, a bottom wall, and a side wall that extends between said top and bottom walls and defines the outer periphery of said frame, said top and bottom walls extending inwardly of said side wall, and further wherein said inverter is mounted to said frame inwardly of said side wall between said top and bottom walls.

7. An AC PV module according to claim 6 wherein said inverter is releasably attached to said side wall.

8. An AC PV module according to claim 6 wherein said inverter comprises a heat-conductive metal housing in heat-conducting contact with at least one of said walls, whereby heat generated by said inverter is dissipated by absorption by said frame member.

9. An AC PV module according to claim 8 wherein said heat-conductive metal housing is in heat-conducting contact with said side and bottom walls.

10. An AC PV module according to claim 8 wherein said PV laminate has a rear surface, and said heat-conductive housing includes a portion that is exposed to the environment behind said rear surface of said photovoltaic laminate.

11. An AC PV module according to claim 6 in combination with support members engaged with two opposite frame members for mounting and securing said module to an underlying support structure so that said rear surface of said photovoltaic laminate is spaced from said underlying support structure to permit air to flow between said module and said underlying support structure.

12. An AC PV module according to claim 11 wherein said support structure is a roof and said support members are connected to said roof.

13. An AC PV module according to claim 11 wherein said frame includes a support-captivating member at opposite sides of said module, and each of said captivating members is releasably coupled to one or more of said support members.

14. An AC PV module according to claim 13 wherein each support-captivating member comprises a flange on the outer side of said frame that defines a support-receiving channel, and further wherein each support member has a bottom end adapted to anchor said support member to said underlying support structure and a top end that is sized to fit in said support-receiving channel.

15. An AC PV module according to claim 1, further including a second like PV module disposed in co-planar relation therewith, and removable first and second connector members coupling said frame of said PV module to the frame of said second like PV module, and further wherein said AC bus is connected to the output sections of the inverters of both modules, said AC bus extending within said elongate channels of said one frame members of both modules and also along a channel defined by said first connector member.

16. A PV module according to claim 1 wherein said PV laminate has front and rear surfaces and has a rectangular configuration defined by four side edge portions and four corners formed by four said side edge portions, said frame comprises individual frame members attached to each of said four side edge portions and abutting one another at said four corners, and further wherein at least one of said corners is characterized by a gap formed in said frame on the front side thereof for draining moisture accumulating on said front surface.

17. A PV module according to claim 1 wherein said module comprises at least two photovoltaic laminates surrounded and supported by said frame, and further wherein each module includes an interface rail interposed between and overlapping adjacent end portions of said at least two photovoltaic laminates, said interface rail being anchored at its opposite ends to said frame.

18. A first AC PV module and at least a second like AC PV module, each module comprising:
a rectangular photovoltaic laminate having front and rear surfaces and DC electrical output terminals;
a substantially rigid frame surrounding and overlapping edge portions of said photovoltaic laminate, said frame comprising first and second mutually parallel frame members connected to and extending between opposite ends of third and fourth opposite frame members, each of said frame members being made of a heat-conductive metal and defining an elongate channel extending parallel to an edge portion of said photovoltaic laminate;
an electrical inverter having an input section and an output section with said input section connected to said DC electrical output terminals, said inverter having a heat-conducting metal housing intruding into said elongate channel of said first frame member;
means mounting said inverter to said first frame member with said housing in heat-conducting engagement with first frame member;
an electrical cable disposed within said elongate channel of said first frame member, said cable being connected to the output section of said inverter whereby to convey the AC power output of said inverter; and
a first connector attached to and extending between said first frame members of said first and second modules and a second connector attached to and extending between said second frame members of said first and second modules;
first frame members of both modules and said first connector having openings, said electrical cable of said first module being connected to said electrical cable of said second module via said openings and said first connector.

19. The combination of claim 18 wherein each of said modules includes captivating flanges on outer surfaces of each of two opposite ones of said frame members, said captivating flanges defining channels of limited width extending lengthwise of the frame members with which they are associated; and further including support members sized to fit within said channels of limited width for mounting said modules to and in spaced relation with an underlying support structure so as to permit air to flow between said modules and said underlying support structure, said support members and modules being movable relative to one another lengthwise of said channels of limited width, and means engaged with said flanges for releasably locking modules to said support members.

20. The combination of claim 19 wherein said captivating flanges are integral parts of said first and second frame members of said modules, whereby said modules are supported at said first and second frame members thereof by said support members.

21. The combination of claim 19 wherein said modules are mounted by said support members on an underlying support structure so that said first and second frame members extend horizontally and said modules are inclined with said second frame members disposed at a higher elevation than said first frame members.

22. The combination of claim 18 wherein said first and second connectors hold said two modules in spaced and co-planar relation with one another.

23. The combination of claim 19 wherein portions of said connectors extend into said channels of limited width, and further including means engaged with said captivating flanges for releasably locking said portions of said connectors to said captivating flanges.

24. The combination of claim 18 wherein each module comprises at least two photovoltaic laminates surrounded and supported by said frame, and further wherein each module includes an interface rail interposed between and overlapping end portions of said at least two PV laminates, said interface rail being anchored at its opposite ends to said frame.

25. The combination of claim 24 further including a cap for said interface rail.

26. A plurality of like AC PV modules each comprising:
at least one photovoltaic laminate having a front surface, a rear surface, and DC electrical output conductors protruding from said laminate;
a substantially rigid frame surrounding and supporting said at least one PV laminate, said frame comprising first, second, third and fourth frame members each having portions thereof overlapping edge portions of said laminate's front and rear surfaces, said first and second frame members being parallel to one another and extending perpendicular to said third and fourth frame members, at least said first and second frame members comprising integral walls that define an elongate channel extending lengthwise of said first and second frame members and projecting rearward of said rear surface of said laminate an electrical inverter disposed within said elongate channels of said first frame members, said inverter comprising a metal housing in heat-conducting and electrical grounding relation with said first frame members, said inverter having a DC input section and an AC output section with said DC input section being connected to said DC electrical output conductors of said laminate;
said modules being aligned a row in co-planar relationship with one another;
first and second connector members mechanically connecting each module to an adjacent module in the row so as to maintain the modules in said co-planar relationship, said first and second connector members being releasably attached to first and second frame members respectively of immediately adjacent modules and functioning as heat-conductors and electrical ground paths between said modules; and
an AC bus interconnecting all of the output sections of said inverters, said AC bus disposed within and extending along said elongate channels of said first frame members and also along said connector members.

27. The combination of claim 26 wherein said modules are mounted on and in spaced relation to a supporting structure so that said first and second frame members extend horizontally and so that said first frame members are disposed at a lower elevation than said second frame members, whereby to promote cooling of said inverters by upward air flow between said support structure and said modules.

28. The combination of claim 26 wherein said first connectors are hollow and said AC bus is routed out of the elongate channel of the first frame member of one module through a first connector into the elongate channel of the first frame member of the immediately adjacent module.

29. The combination of claim 26 further including means for mounting said row of modules on a roof in spaced relation to that roof, said mounting means comprising at least first and second mounting stands for each module, with at least one first mounting stand coupled to one frame member of a module and at least one second mounting stand coupled to a second opposite frame member of the same module, and each mounting stand comprising a base portion adapted to be engaged with a roof structure and a second upstanding portion, and further wherein said first and second frame members each includes means for making an interlocking connection with said second upstanding portions of said mounting stands whereby to lock said modules to said stands.

30. The combination of claim 26 wherein said modules are disposed in at least two parallel rows, and further including a plurality of first and second mounting stands for mounting said two row of modules on a roof in spaced relation to that roof, at least some of said first and second mounting stands comprising a base portion adapted to be engaged with a roof structure and first and second mutually spaced upstanding portions, said first upstanding portions being engaged with said first frame members of the modules in one row in module supporting relation therewith, and said second upstanding portions being engaged with said second frame members of the modules in the adjacent row in module supporting relation therewith, and further including means for locking said first and second upstanding portions of said mounting stands to said modules.

31. The combination of claim 26 wherein each module comprises two PV laminates surrounded and supported by said frame, and further including an interface rail interposed between said laminates and attached at its ends to said frame.
